(19) United States
(12) Patent Application Publication
(10) Pub. No.: US 2010/0259465 A1
(43) Pub. Date: Oct. 14, 2010

(54) OUTPUT BUFFER, SOURCE DRIVER, AND DISPLAY DEVICE UTILIZING THE SAME

(75) Inventor: Yu-Jui Chang, Tainan County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: HIMAX TECHNOLOGIES LIMITED, Tainan County (TW)

(21) Appl. No.: 12/420,978

(22) Filed: Apr. 9, 2009

(51) Int. Cl. G09G 3/20; H03L 5/00; H03K 19/0175

(52) U.S. Cl. 345/55; 327/333; 326/83; 327/108

(57) ABSTRACT

An output buffer providing a data signal to a data line and including an input stage circuit, an output stage circuit, and a control circuit is disclosed. The input stage circuit receives an input signal. The output stage circuit generates the data signal according to the input signal and includes a first P-type transistor. The control circuit selectively provides a first voltage or a second voltage to a bulk of the first P-type transistor.

### BACKGROUND OF THE INVENTION

1. Field of the Invention

The invention relates to an output buffer, and more particularly to an output buffer applied to a source driver of a display device.

2. Description of the Related Art

FIG. 1 is a schematic diagram of a conventional output buffer. The output buffer 100 comprises an input stage circuit 110 and an output stage circuit 130. The output stage circuit 130 comprises a P-type transistor 131. The source and the bulk of the P-type transistor 131 receive the voltage VDDA. The voltage VDDA is a maximum voltage in the corresponding circuit.

The output buffer is commonly in many applications, especially in display application. To increase resolution, the number of the output buffer is required to increase such that the power consumption is increased.

### BRIEF SUMMARY OF THE INVENTION

Output buffers are provided. An exemplary embodiment of an output buffer, which provides a data signal to a data line, comprises an input stage circuit, an output stage circuit, and a control circuit. The input stage circuit receives an input signal. The output stage circuit generates the data signal according to the input signal and comprises a first P-type transistor. The control circuit selectively provides a first voltage or a second voltage to a bulk of the first P-type transistor.

Source drivers are provided. An exemplary embodiment of a source driver, which provides at least one data signal to at least one data line, comprises a digital-to-analog converter and an output buffer. The digital-to-analog converter provides an analog signal. The output buffer comprises an input stage circuit, an output stage circuit, and a control circuit. The input stage circuit receives the analog signal. The output stage circuit generates the data signal according to the analog signal and comprises a first P-type transistor. The control circuit selectively provides a first voltage or a second voltage to a bulk of the first P-type transistor.

Display devices are also provided. An exemplary embodiment of a display device comprises at least one data line and a source driver. The source driver provides a data signal to the data line and comprises a digital-to-analog converter and an output buffer. The digital-to-analog converter provides an analog signal. The output buffer comprises an input stage circuit, an output stage circuit, and a control circuit. The input stage circuit receives the analog signal. The output stage circuit generates the data signal according to the analog signal and comprises a first P-type transistor. The control circuit selectively provides a first voltage or a second voltage to a bulk of the first P-type transistor.

A detailed description is given in the following embodiments with reference to the accompanying drawings.

### BRIEF DESCRIPTION OF THE DRAWINGS

The invention can be more fully understood by referring to the following detailed description and examples with references made to the accompanying drawings, wherein:

FIG. 1 is a schematic diagram of a conventional output buffer;

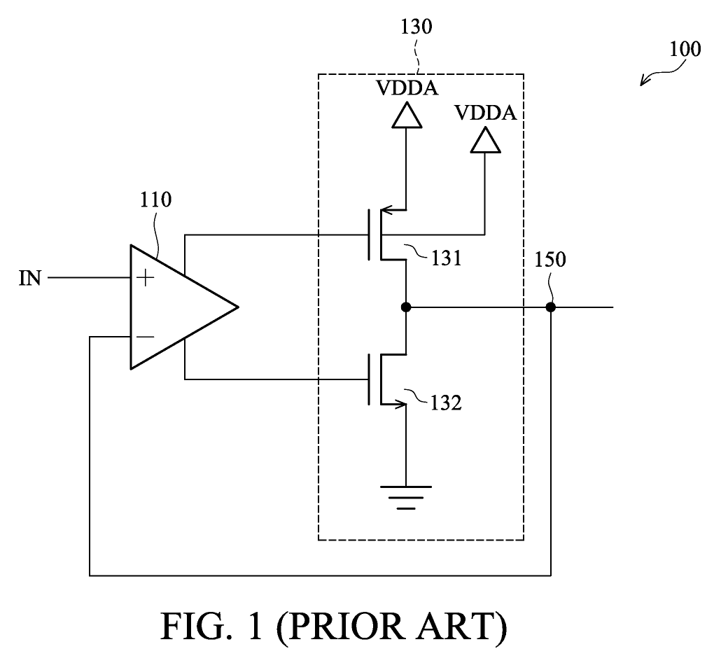

FIG. 2 is a schematic diagram of an exemplary embodiment of a display device; and

FIG. 3 is a schematic diagram of an exemplary embodiment of a source driver.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

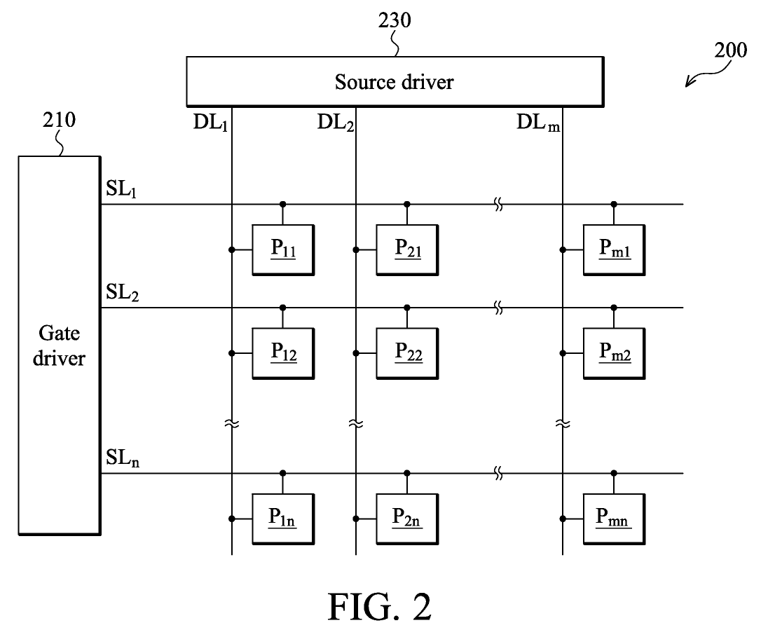

FIG. 2 is a schematic diagram of an exemplary embodiment of a display device. The display device 200 comprises a gate driver 210, a source driver 230, and pixels P₁₁˜Pₘₙ. The gate driver 210 provides scan signals to the pixels P₁₁˜Pₘₙ via the scan lines SL₁˜SLₙ. The source driver 230 provides data signals to the pixels P₁₁˜Pₘₙ via the data lines DL₁˜DLₘ. The pixels P₁₁˜Pₘ receive the data signals according to the scan signals and display brightness according to the data signals.

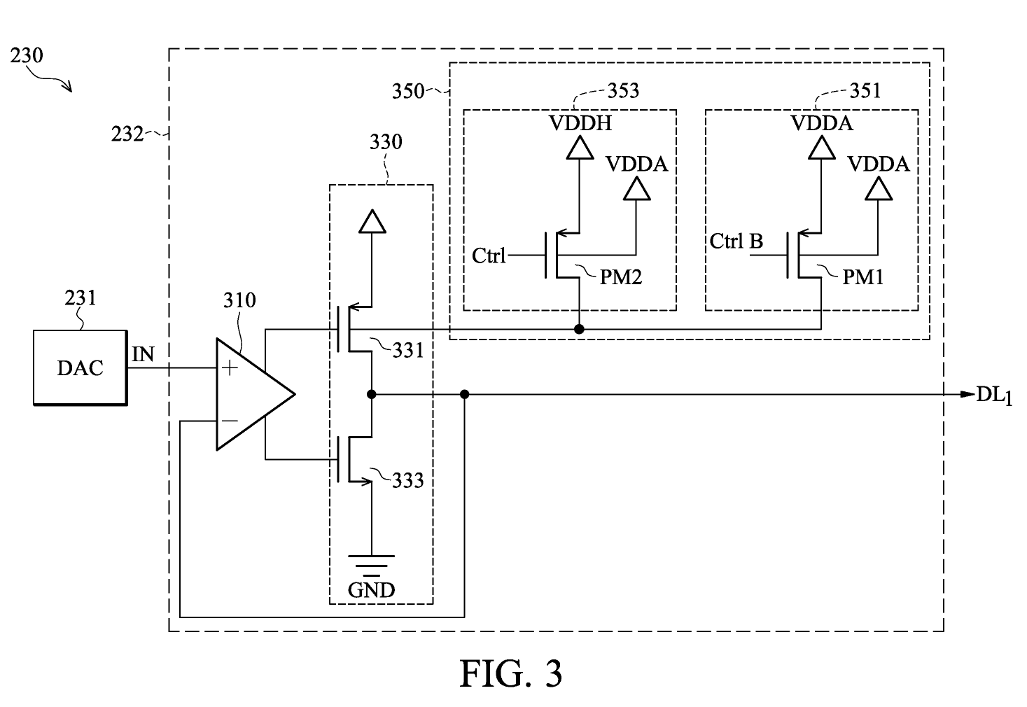

FIG. 3 is a schematic diagram of an exemplary embodiment of a source driver. The source driver 230 is capable of providing various data signals to data lines DL₁˜DLₘ. For clarity, the source driver 230 as shown in FIG. 3 only provides a single data signal to the data line DL₁. The source driver 230 as shown in FIG. 3 comprises a digital-to analog converter (DAC) 231 and an output buffer 232.

The DAC 231 provides an analog signal IN. The output buffer 232 comprises an input stage circuit 310, an output stage circuit 330, and a control circuit 350. The input stage circuit 310 receives the analog signal IN. The output stage circuit 330 generates a data signal to the data line DL₁ according to the analog signal IN. The output stage circuit 330 comprises a P-type transistor 331. The control circuit 350 selectively provides a first voltage VDDA or a second voltage VDDH to the bulk of the P-type transistor 331. In the exemplary embodiments of the present invention, it is assumed that the first voltage VDDA is a maximum voltage in the corresponding circuit and the second voltage VDDH is less than the first voltage VDDA.

In one embodiment, when the voltage range of the data signal is from 0 to the second voltage VDDH, the source voltage of the P-type transistor 331 couples to the second voltage VDDH rather than the first voltage VDDA to save power consumption. When the source voltage of the P-type transistor 331 is equal to the second voltage VDDH and the first voltage VDDA is continuously transmitted to the bulk of the P-type transistor 331, a body effect may occur in the P-type transistor 331 during operating the output buffer 230. Thus, the control circuit 350 is utilized to provide the second voltage VDDH to the bulk of the P-type transistor 331. In other embodiment, the control circuit 350 sequentially provides the first voltage VDDA and the second voltage VDDH to the bulk of the P-type transistor 331 while the output stage circuit 330 generates the data signal to the data line DL₁.

Specifically, when the output buffer 232 outputs a data signal and the voltage range of the data signal is from 0 to the second voltage VDDH, the second voltage VDDH is transmitted to the source and the bulk of the P-type transistor 331. Thus, a body effect does not be occurred in the P-type transistor 331. Furthermore, assuming that the bulk voltage of the P-type transistor 331 receives the second voltage VDDH. In this case, if the previous data signal level on the data line DL₁ exceeds the second voltage VDDH, a leakage current effect may occur in the P-type transistor 331. Accordingly, when the output buffer 232 outputs a data signal, the first voltage VDDA is first transmitted to the bulk of the P-type transistor 331 and then the second voltage VDDH is transmitted to the bulk of the P-type transistor 331. Since the voltage (VDDH or VDDA) is selectively transmitted to the bulk of the P-type transistor 331, the leakage current effect and the body effect are improved and the power consumption of the output buffer can be reduced effectively.

For example, the control circuit 350 provides the first voltage VDDA to the bulk of the P-type transistor 331 while the output stage circuit 330 starts to generate the data signal. After a moment, the control circuit 350 sequentially provides the second voltage VDDH less than the first voltage VDDA to the bulk of the P-type transistor 331.

In the embodiment of the present invention, assuming the voltage range of the data signal generated by the output buffer 232 is from 0 to the second voltage VDDH, wherein the second voltage VDDH is substantially equal to the half of the first voltage VDDA, or maybe larger than the half of the first voltage VDDA, but is not limited. To save power consumption, the source of the P-type transistor 331 receives the second voltage VDDH.

The control circuit 350 comprises switching units 351 and 353. The switching unit 351 transmits the first voltage VDDA to the bulk of the P-type transistor 331 according to a control signal CtrlB. The switching unit 353 transmits the second voltage VDDH to the bulk of the P-type transistor 331 according to a control signal Ctrl.

In this embodiment, the switching unit 351 is constituted by a P-type transistor PM1 and the switching unit 353 is constituted by a P-type transistor PM2. The bulks of the P-type transistors PM1 and PM2 receive the first voltage VDDA. The control signals Ctrl and CtrlB are complementary signals such that the P-type transistors PM1 and PM2 are not turned on simultaneously.

In addition, the output stage circuit 330 further comprises an N-type transistor 333. The N-type transistor 333 and the P-type transistor 331 are serially connected and a source of the N-type transistor 333 connects to a grounding voltage GND. The grounding voltage GND is less than the second voltage VDDH.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An output buffer providing a data signal to a data line, comprising:
an input stage circuit receiving an input signal;
an output stage circuit generating the data signal according to the input signal and comprising a first P-type transistor; and
a control circuit selectively providing a first voltage or a second voltage to a bulk of the first P-type transistor.

2. The output buffer as claimed in claim 1, wherein the control circuit sequentially provides the first and the second voltage to the bulk of the first P-type transistor while the output stage circuit generates the data signal.

3. The output buffer as claimed in claim 2, wherein the first voltage exceeds the second voltage.

4. The output buffer as claimed in claim 3, wherein a voltage of a source of the first P-type transistor is substantially equal to the second voltage.

5. The output buffer as claimed in claim 1, wherein the output stage circuit further comprises an N-type transistor serially connected to the first P-type transistor.

6. The output buffer as claimed in claim 1, wherein the control circuit comprises:
a first switching unit transmitting the first voltage to the first P-type transistor according to a first control signal; and
a second switching unit transmitting the second voltage to the first P-type transistor according to a second control signal.

7. The output buffer as claimed in claim 6, wherein the first switching unit is a second P-type transistor, the second switching unit is a third P-type transistor, and bulks of the second and the third P-type transistors receive the first voltage.

8. The output buffer as claimed in claim 7, wherein the first and the second control signals are complementary signals.

9. A source driver providing at least one data signal to at least one data line, comprising:
a digital-to-analog converter providing an analog signal; and
an output buffer comprising:
an input stage circuit receiving the analog signal;
an output stage circuit generating the data signal according to the analog signal and comprising a first P-type transistor; and
a control circuit selectively providing a first voltage or a second voltage to a bulk of the first P-type transistor.

10. The source driver as claimed in claim 9, wherein the control circuit sequentially provides the first and the second voltage to the bulk of the first P-type transistor while the output stage circuit generates the data signal.

11. The source driver as claimed in claim 10, wherein the first voltage exceeds the second voltage.

12. The source driver as claimed in claim 11, wherein a voltage of a source of the first P-type transistor is substantially equal to the second voltage.

13. The source driver as claimed in claim 9, wherein the control circuit comprises:
a first switching unit transmitting the first voltage to the first P-type transistor according to a first control signal; and
a second switching unit transmitting the second voltage to the first P-type transistor according to a second control signal.

14. The source driver as claimed in claim 13, wherein the first switching unit is a second P-type transistor, the second switching unit is a third P-type transistor, and bulks of the second and the third P-type transistors receive the first voltage.

15. The source driver as claimed in claim 14, wherein the first and the second control signals are complementary signals.

16. A display device, comprising:
at least one data line; and
a source driver providing a data signal to the data line and comprising:
a digital-to-analog converter providing an analog signal; and
an output buffer comprising:
an input stage circuit receiving the analog signal;
an output stage circuit generating the data signal according to the analog signal and comprising a first P-type transistor; and
a control circuit selectively providing a first voltage or a second voltage to a bulk of the first P-type transistor.

17. The source driver as claimed in claim 16, wherein the control circuit sequentially provides the first and the second voltage to the bulk of the first P-type transistor while the output stage circuit generates the data signal.

18. The source driver as claimed in claim 17, wherein a voltage of a source of the first P-type transistor is substantially equal to the second voltage.

19. The display device as claimed in claim 16, wherein the control circuit comprises:
a first switching unit transmitting the first voltage to the first P-type transistor according to a first control signal; and
a second switching unit transmitting the second voltage to the first P-type transistor according to a second control signal.

20. The display device as claimed in claim 19, wherein the first switching unit is a second P-type transistor, the second switching unit is a third P-type transistor, and bulks of the second and the third P-type transistors receive the first voltage.
